(19) United States
(12) Patent Application Publication
(10) Pub. No.: US 2025/0344607 A1
(43) Pub. Date: Nov. 6, 2025

(54) MAGNETORESISTIVE RANDOM ACCESS MEMORY AND METHOD FOR FABRICATING THE SAME

(71) Applicant: UNITED MICROELECTRONICS CORP., Hsin-Chu City (TW)

(72) Inventor: Hui-Lin Wang, Taipei City (TW)

(73) Assignee: UNITED MICROELECTRONICS CORP., Hsin-Chu City (TW)

(21) Appl. No.: 18/746,090

(22) Filed: Jun. 18, 2024

(30) Foreign Application Priority Data
May 6, 2024 (TW) 113116629

(51) Int. Cl. H10N 50/01; H10B 61/00; H10N 50/10

(52) U.S. Cl. CPC H10N 50/01; H10B 61/20; H10N 50/10

(57) ABSTRACT

A method for fabricating a magnetoresistive random access memory (MRAM) device includes the steps of first forming a spin orbit torque (SOT) layer on a substrate, forming a magnetic tunneling junction (MTJ) on the SOT layer, forming a first cap layer adjacent to the MTJ, and then performing an ion implantation process to form a first doped region in the SOT layer adjacent to one side of the MTJ and a second doped region in the SOT layer adjacent to another side of the MTJ. Preferably, the first doped region and the second doped region constitute a ring around the MTJ in a top view.

### BACKGROUND OF THE INVENTION

### 1. Field of the Invention

The invention relates to a semiconductor device and method for fabricating the same, and more particularly to a magnetoresistive random access memory (MRAM) and method for fabricating the same.

### 2. Description of the Prior Art

Magnetoresistance (MR) effect has been known as a kind of effect caused by altering the resistance of a material through variation of outside magnetic field. The physical definition of such effect is defined as a variation in resistance obtained by dividing a difference in resistance under no magnetic interference by the original resistance. Currently, MR effect has been successfully utilized in production of hard disks thereby having important commercial values. Moreover, the characterization of utilizing GMR materials to generate different resistance under different magnetized states could also be used to fabricate MRAM devices, which typically has the advantage of keeping stored data even when the device is not connected to an electrical source.

The aforementioned MR effect has also been used in magnetic field sensor areas including but not limited to for example electronic compass components used in global positioning system (GPS) of cellular phones for providing information regarding moving location to users. Currently, various magnetic field sensor technologies such as anisotropic magnetoresistance (AMR) sensors, GMR sensors, magnetic tunneling junction (MTJ) sensors have been widely developed in the market. Nevertheless, most of these products still pose numerous shortcomings such as high chip area, high cost, high power consumption, limited sensibility, and easily affected by temperature variation and how to come up with an improved device to resolve these issues has become an important task in this field.

### SUMMARY OF THE INVENTION

According to an embodiment of the present invention, a method for fabricating a magnetoresistive random access memory (MRAM) device includes the steps of first forming a spin orbit torque (SOT) layer on a substrate, forming a magnetic tunneling junction (MTJ) on the SOT layer, forming a first cap layer adjacent to the MTJ, and then performing an ion implantation process to form a first doped region in the SOT layer adjacent to one side of the MTJ and a second doped region in the SOT layer adjacent to another side of the MTJ. Preferably, the first doped region and the second doped region constitute a ring around the MTJ in a top view.

According to another aspect of the present invention, a magnetoresistive random access memory (MRAM) device includes a spin orbit torque (SOT) layer on a substrate, a magnetic tunneling junction (MTJ) on the SOT layer, a first doped region in the SOT layer adjacent to one side of the MTJ, and a second doped region in the SOT layer adjacent to another side of the MTJ.

According to yet another aspect of the present invention, a magnetoresistive random access memory (MRAM) device includes a spin orbit torque (SOT) layer on a substrate, a magnetic tunneling junction (MTJ) on the SOT layer, and a doped region in the SOT layer to surround the MTJ. Preferably, doped region includes a first recess in a top view.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-7 illustrate a method for fabricating a MRAM device according to an embodiment of the present invention.

FIGS. 8-14 illustrate a method for fabricating a MRAM device according to an embodiment of the present invention.

FIG. 15 illustrates top views of a MRAM device according to different embodiments of the present invention.

### DETAILED DESCRIPTION

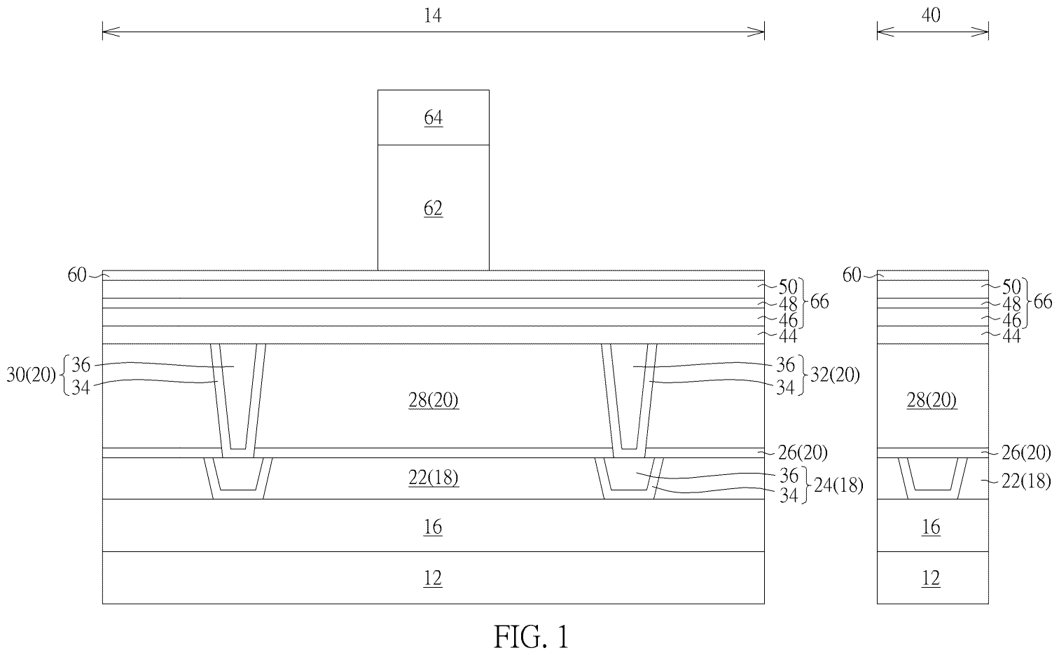

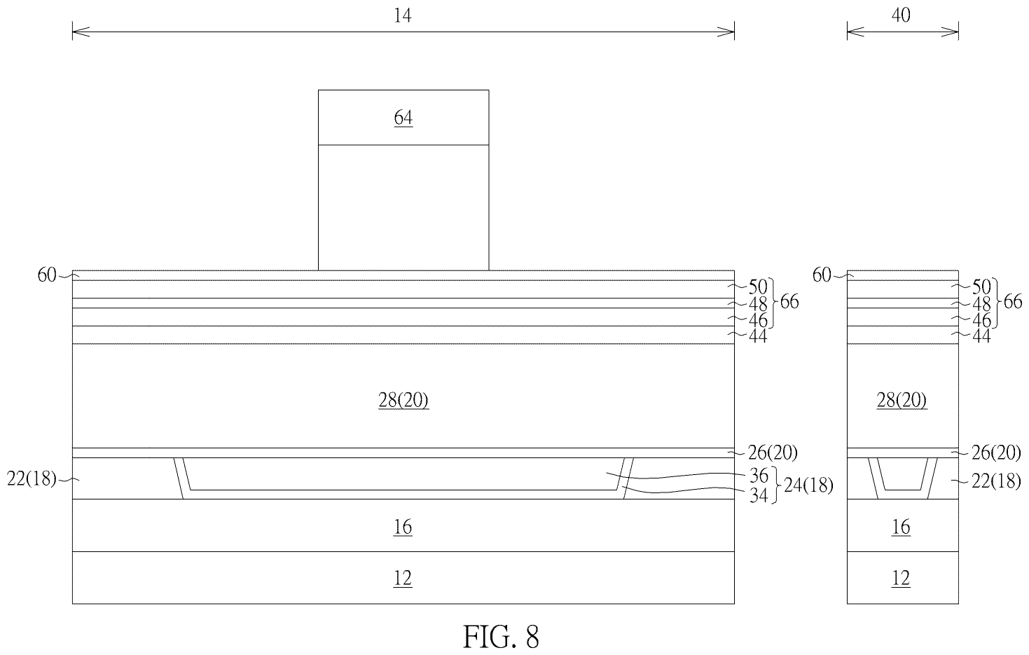

Referring to FIGS. 1-14, FIGS. 1-14 illustrate a method for fabricating a semiconductor device, or more specifically a MRAM device according to an embodiment of the present invention, in which FIGS. 1-7 illustrate a method for fabricating the MRAM device along Y-direction according to an embodiment of the present invention and FIGS. 8-14 illustrate a method for fabricating the MRAM device along X-direction according to an embodiment of the present invention. As shown in FIGS. 1 and 8, a substrate 12 made of semiconductor material is first provided, in which the semiconductor material could be selected from the group consisting of silicon (Si), germanium (Ge), Si—Ge compounds, silicon carbide (SiC), and gallium arsenide (GaAs), and a MRAM region 14 and a logic region 40 are defined on the substrate 12.

Active devices such as metal-oxide semiconductor (MOS) transistors, passive devices, conductive layers, and interlayer dielectric (ILD) layer 16 could also be formed on top of the substrate 12. More specifically, planar MOS transistors or non-planar (such as FinFETs) MOS transistors could be formed on the substrate 12, in which the MOS transistors could include transistor elements such as gate structures (for example metal gates) and source/drain region, spacer, epitaxial layer, and contact etch stop layer (CESL). The ILD layer 16 could be formed on the substrate 12 to cover the MOS transistors, and a plurality of contact plugs could be formed in the ILD layer 16 to electrically connect to the gate structure and/or source/drain region of MOS transistors. Since the fabrication of planar or non-planar transistors and ILD layer is well known to those skilled in the art, the details of which are not explained herein for the sake of brevity.

Next, metal interconnect structures 18, 20 are sequentially formed on the ILD layer 16 to electrically connect the aforementioned contact plugs, in which the metal interconnect structure 18 includes an inter-metal dielectric (IMD) layer 22 and metal interconnections 24 embedded in the IMD layer 22, and the metal interconnect structure 20 includes a stop layer 26, an IMD layer 28, and metal interconnections 30, 32 embedded in the stop layer 26 and the IMD layer 28. It should be noted that in contrast to metal interconnections 24, 30, 32 are disposed in the IMD layers 24, 28 on the MRAM region 14, only metal interconnection 24 is embedded in the IMD layer 22 while no metal interconnection is disposed in the IMD layer 28 on the logic region 40 at this stage. Moreover, even though metal interconnections 30, 32 are disposed in the IMD layer 28 along the Y-direction in FIG. 1, no metal interconnection however is disposed in the IMD layer along the X-direction in FIG. 8.

In this embodiment, each of the metal interconnections 24 from the metal interconnect structure 18 preferably includes a trench conductor and each of the metal interconnections 30, 32 from the metal interconnect structure 20 includes a via conductor. Preferably, each of the metal interconnections 24, 30, 32 from the metal interconnect structures 18, 20 could be embedded within the IMD layers 22, 28 and/or stop layer 26 according to a single damascene process or dual damascene process. For instance, each of the metal interconnections 24, 30, 32 could further include a barrier layer 34 and a metal layer 36, in which the barrier layer 34 could be selected from the group consisting of titanium (Ti), titanium nitride (TiN), tantalum (Ta), and tantalum nitride (TaN) and the metal layer 36 could be selected from the group consisting of tungsten (W), copper (Cu), aluminum (Al), titanium aluminide (TiAl), and cobalt tungsten phosphide (CoWP). Since single damascene process and dual damascene process are well known to those skilled in the art, the details of which are not explained herein for the sake of brevity. In this embodiment, the metal layers 36 in the metal interconnections 24 are preferably made of copper, the metal layers 36 in the metal interconnections 30, 32 are preferably made of tungsten, the IMD layers 22, 28 are preferably made of silicon oxide or ultra low-k (ULK) dielectric layer, and the stop layers 26 is preferably made of nitrogen doped carbide (NDC), silicon nitride, silicon carbon nitride (SiCN), or combination thereof.

Next, a selective bottom electrode 42, a spin orbit torque (SOT) layer 44, a MTJ stack 66, a cap layer 60, and a patterned mask or top electrode (TE) 62 are formed on the metal interconnect structure 20. In this embodiment, the formation of the MTJ stack 66 could be accomplished by sequentially depositing a free layer 46, a barrier layer 48, a reference layer (not shown), a spacer (not shown), and a pinned layer 50 on the SOT layer 44. Preferably, the free layer 46 could be made of ferromagnetic material including but not limited to for example iron, cobalt, nickel, or alloys thereof such as cobalt-iron-boron (CoFeB), in which the magnetized direction of the free layer 46 could be altered freely depending on the influence of outside magnetic field. The barrier layer 48 could be made of insulating material including but not limited to for example oxides such as aluminum oxide (AlOₓ) or magnesium oxide (MgO).

The reference layer is disposed between the barrier layer 48 and the spacer, in which the reference layer could be made of ferromagnetic material including but not limited to for example iron, cobalt, nickel, or alloys thereof such as cobalt-iron-boron (CoFeB). The spacer could be a non-magnetic layer made of non-magnetic material including but not limited to for example ruthenium (Ru), iridium (Ir), rhodium (Rh), or combination thereof.

The pinned layer 50 could be made of antiferromagnetic (AFM) material including but not limited to for example ferromanganese (FeMn), platinum manganese (PtMn), iridium manganese (IrMn), nickel oxide (NiO), or combination thereof, in which the pinned layer 50 is formed to fix or limit the direction of magnetic moment of adjacent layers. Specifically, the pinned layer 50 further includes a bottom synthetic antiferromagnetic (SAF) layer, a coupling layer, and a top SAF layer, in which the bottom SAF layer and the top SAF layer could include same or different materials while both layers could include ferromagnetic material such as cobalt (Co), nickel (Ni), platinum (Pt), palladium (Pd), or combination thereof. The coupling layer may also include materials to provide mechanical and/or crystalline structural support for the bottom SAF layer and the top SAF layer. Preferably, the coupling layer includes material that aides in this coupling including but not limited to ruthenium (Ru), tantalum (Ta), gadolinium (Gd), platinum (Pt), hafnium (Hf), or combination thereof.

Moreover, the selective bottom electrode 42 could include conductive material such as but not limited to for example Ta, TaN, Pt, Cu, Au, Al, or combination thereof, the SOT layer 44 is serving as a channel for the MRAM device as the SOT layer 44 could include metals such as tantalum (Ta), tungsten (W), platinum (Pt), or hafnium (Hf) and/or topological insulator such as bismuth selenide (BiₓSe₁₋ₓ). The cap layer 60 preferably includes metal such as Ru, and the TE 62 preferably includes conductive or dielectric material such as tantalum (Ta), tantalum nitride (TaN), titanium (Ti), titanium nitride (TiN), platinum (Pt), copper (Cu), gold (Au), aluminum (Al), or combination thereof.

In this embodiment, the formation of the patterned TE 62 could be accomplished by first forming a dielectric layer 64 made of silicon oxide on an un-patterned TE 62 and then using a patterned mask (not shown) such as patterned resist as mask to remove part of the dielectric layer 64 and part of the TE 62 through reactive ion etching (RIE) process for forming a patterned dielectric layer 64 and a patterned TE 62. The dielectric layer 64 made of silicon oxide could be selectively removed thereafter.

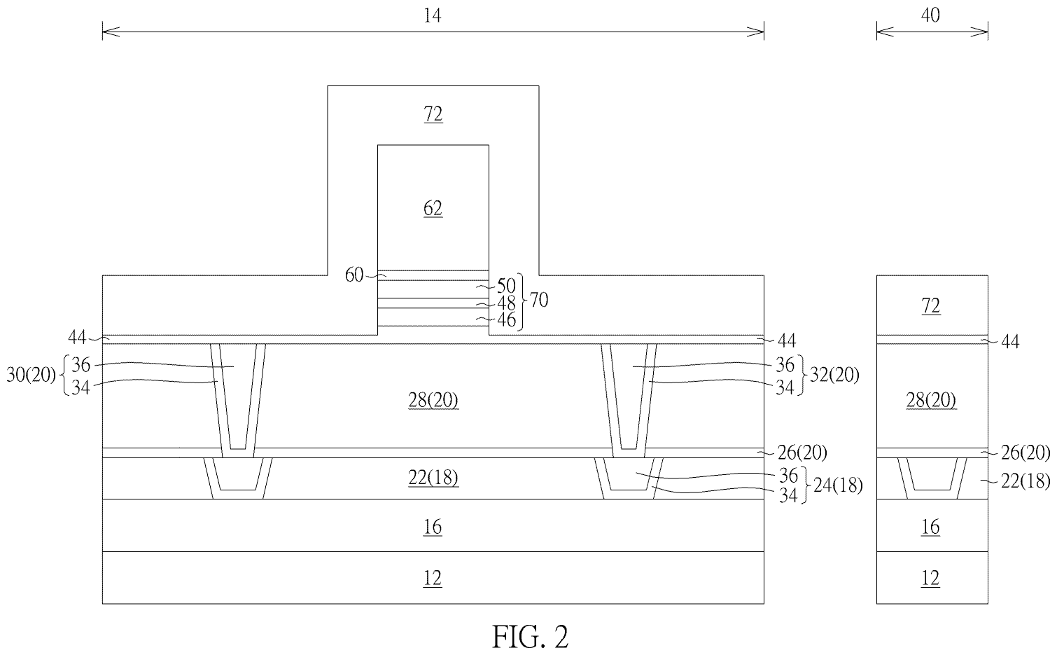

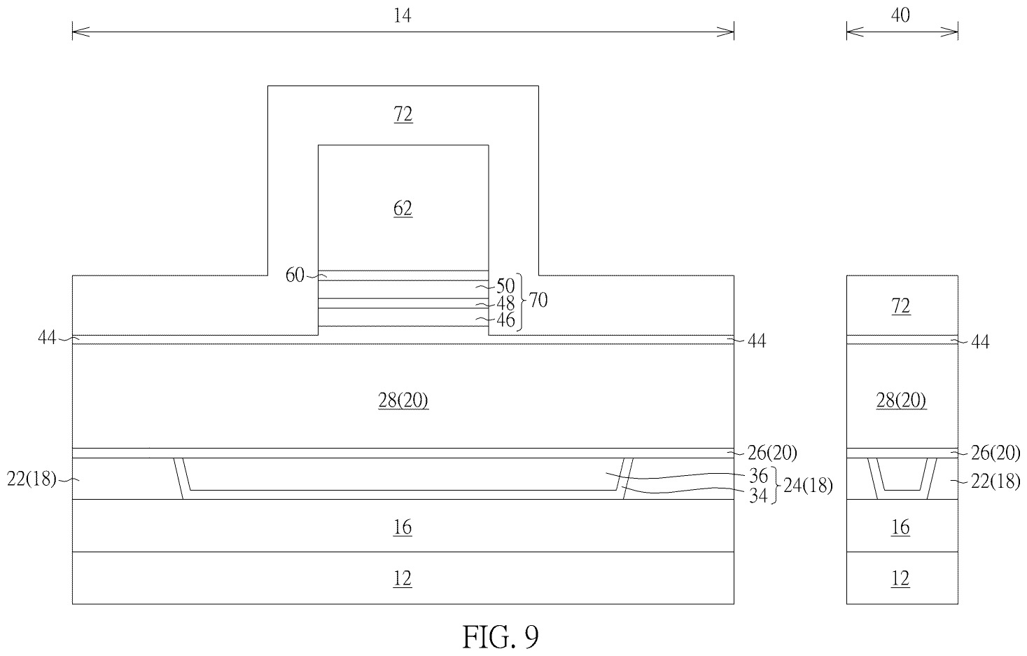

Next, as shown in FIGS. 2 and 9, the patterned dielectric layer 64 or the patterned TE 62 could be used as a mask to remove part of the cap layer 60, part of the MTJ stack 66, and even part of the SOT layer 44 for forming a MTJ 70, and then a first cap layer 72 is formed on the MTJ 70. Preferably, the MTJ stack 66 on the logic region 40 is completely removed at this stage and the first cap layer 72 is made of silicon nitride. It should be noted that when the patterned TE 62 is used to pattern the MTJ stack 66 for forming the MTJ 70, part of the SOT layer 44 could be removed at the same time so that the top surface of the remaining SOT layer 44 adjacent to two sides of the MTJ 70 is slightly lower than the top surface of the SOT layer 44 directly under the MTJ 70. According to an embodiment of the present invention, if none of the SOT layer 44 is removed during the formation of the MTJ 70, the top surface of the SOT layer 44 adjacent to two sides of the MTJ 70 would be even with the top surface of the SOT layer 44 directly under the MTJ 70. Moreover, the first cap layer 72 formed at this stage is preferably disposed on the MRAM region 14 and the logic region 40 at the same time.

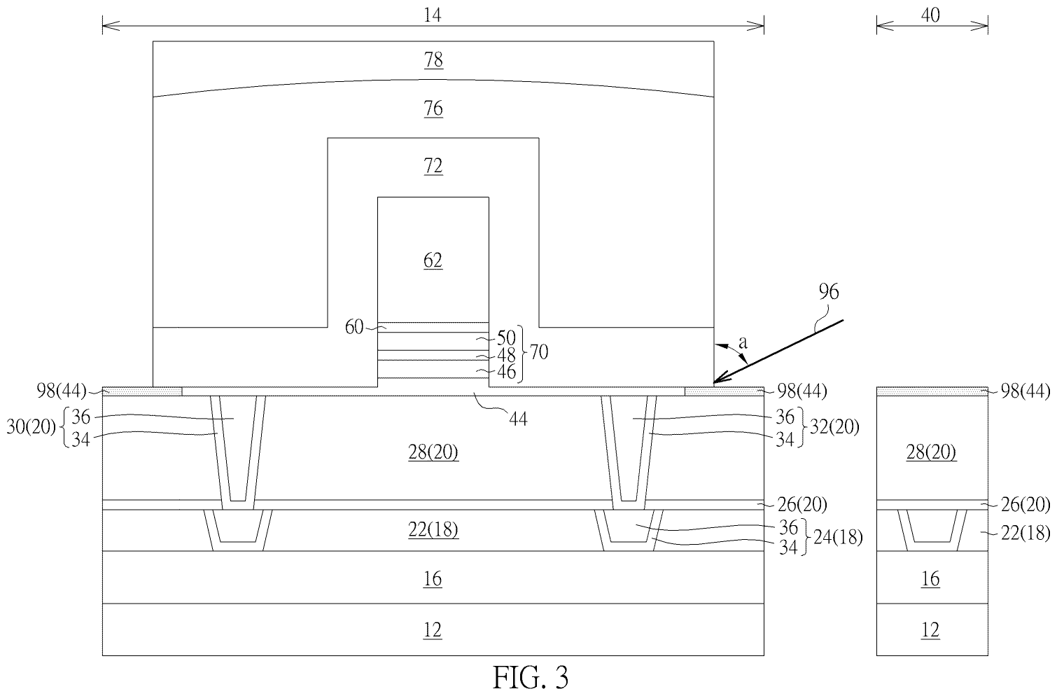

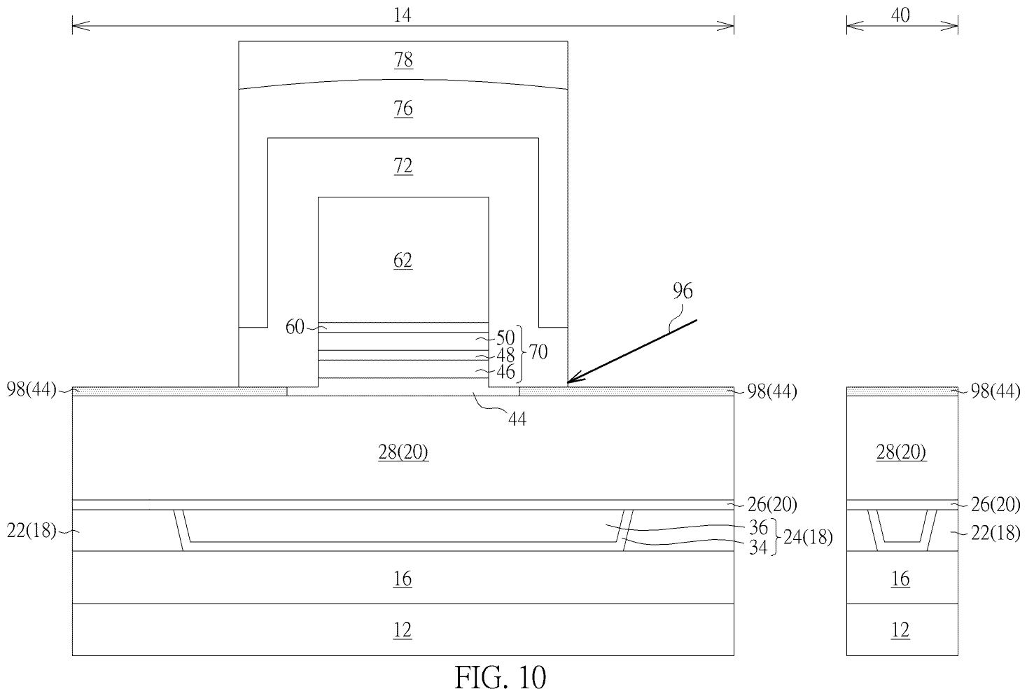

Next, as shown in FIGS. 3 and 10, a bottom anti-reflective coating (BARC) 76 is formed on the first cap layer 72, and then an etching process such as another RIE process is conducted by using a patterned mask 78 such as a patterned resist as mask to remove part of the BARC 76 and part of the cap layer 72 on the MRAM region 14 and all of the BARC 76 and first cap layer 72 on the logic region 40 for exposing the surface of the SOT layer 44 underneath so that the remaining first cap layer 72 is only disposed on the MRAM region 14 while the SOT layer 44 underneath is disposed on both MRAM region 14 and logic region 40.

Next, an ion implantation process 96 could be conducted to implant dopants into the SOT layer 44 adjacent to two sides of the MTJ 70, in which the ion implantation process 96 conducted at this stage is a tilt angle ion implantation process and an angle a included between the implanted ions and sidewall of the first cap layer 72 or sidewall of the BARC 76 is between 65-85 degrees or most preferably less than 70 degrees. Since the ions are implanted at tilt angle into the SOT layer 44 adjacent to two sides of the MTJ 70 at this stage, the ions are not only injected into the SOT layer 44 adjacent to two sides of the first cap layer 72 but also part of the SOT layer 44 directly under the first cap layer 72. This forms doped regions 98 in the SOT layer 44 on both left side and right side of the MTJ 70. It should be noted that the even though the doped regions 98 may seem to be formed adjacent to two sides of the MTJ 70 under a cross-section view in FIG. 3, the doped regions 98 if viewed under a top view perspective are in fact surrounding the entire MTJ 70.

Moreover, since no mask is covered on the logic region 40, a doped region 98 is also formed in the SOT layer 44 on the logic region 44 when ions are implanted into the SOT layer 44 to form the doped regions 98 on the MRAM region 14. In this embodiment, the ions implanted preferably include nitrogen gas (N₂) ions such that if the SOT layer 44 were made of tungsten (W), the doped regions 98 formed in the SOT layer 44 after the implantation process would preferably include metal nitride such as tungsten nitride (WNₓ).

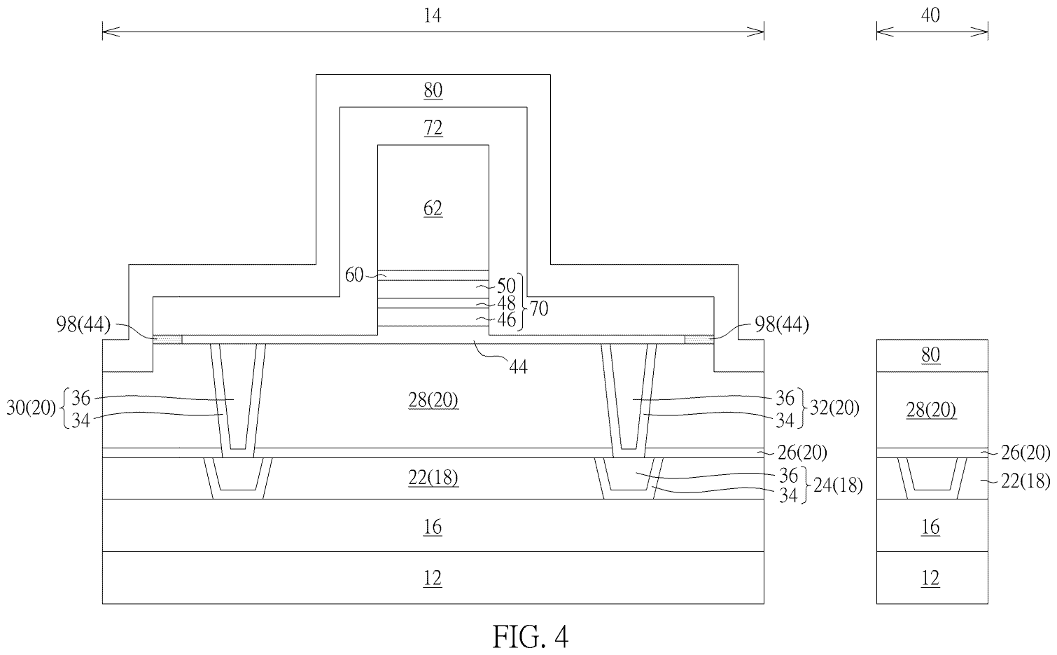

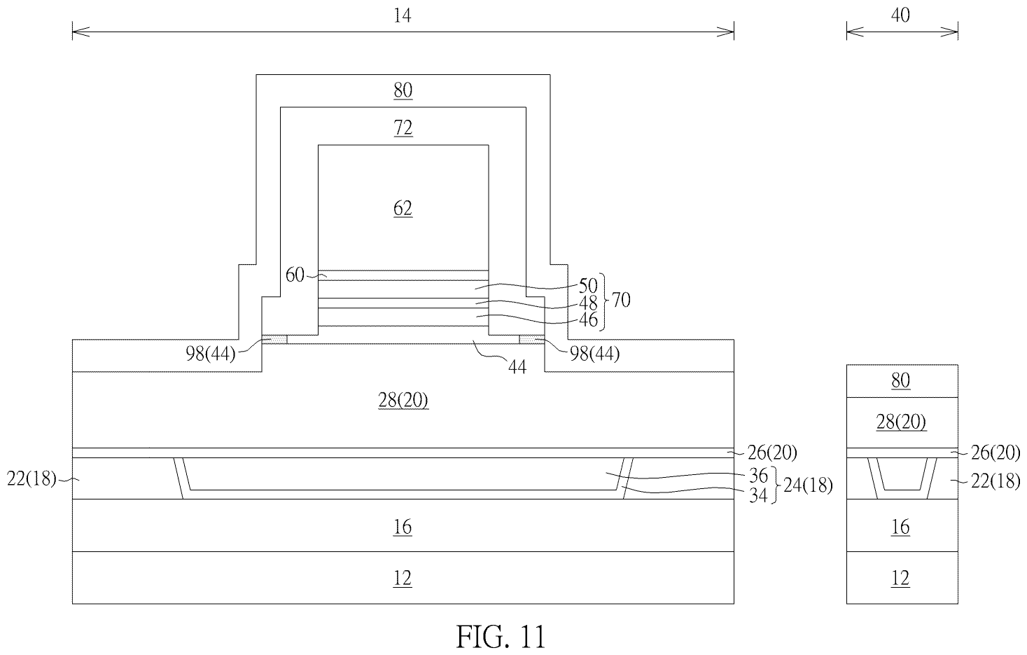

Next, as shown in FIGS. 4 and 11, after stripping the patterned mask 78 and the BARC 76, an etching process such as an ion beam etching (IBE) process is conducted without forming another patterned mask to remove part of the first cap layer 72, part of the SOT layer 44, and even part of the IMD layer 28 on the MRAM region 14 and all of the SOT layer 44 and part of the IMD layer 28 on the logic region 40. This reduces the widths of the first cap layer 72, the SOT layer 44, and even part of the IMD layer 28 on the MRAM region 14 so that the left and right sidewalls of the first cap layer 72, the SOT layer 44, and part of the IMD layer 28 are retracted inward and aligned with each other. The top surface of the remaining IMD layer 28 on the logic region 40 on the other hand could be slightly lower than the top surface of the IMD layer 28 on the MRAM region 14.

Next, a second cap layer 80 is formed on the first cap layer 72 and the IMD layer 28, in which the second cap layer 80 preferably covers the top surface of the first cap layer 72, sidewalls of the first cap layer 72, sidewalls of the SOT layer 44 containing the doped regions 98, and the top surface of the IMD layer 28. In this embodiment, the first cap layer 72 and the second cap layer 80 are preferably made of same material such as silicon nitride (SiN). Since the aforementioned IBE process removes part of the IMD layer 28 adjacent to the metal interconnections 30, 32, the bottom surface of the second cap layer 80 is slightly lower than the bottom surface of the first cap layer 72.

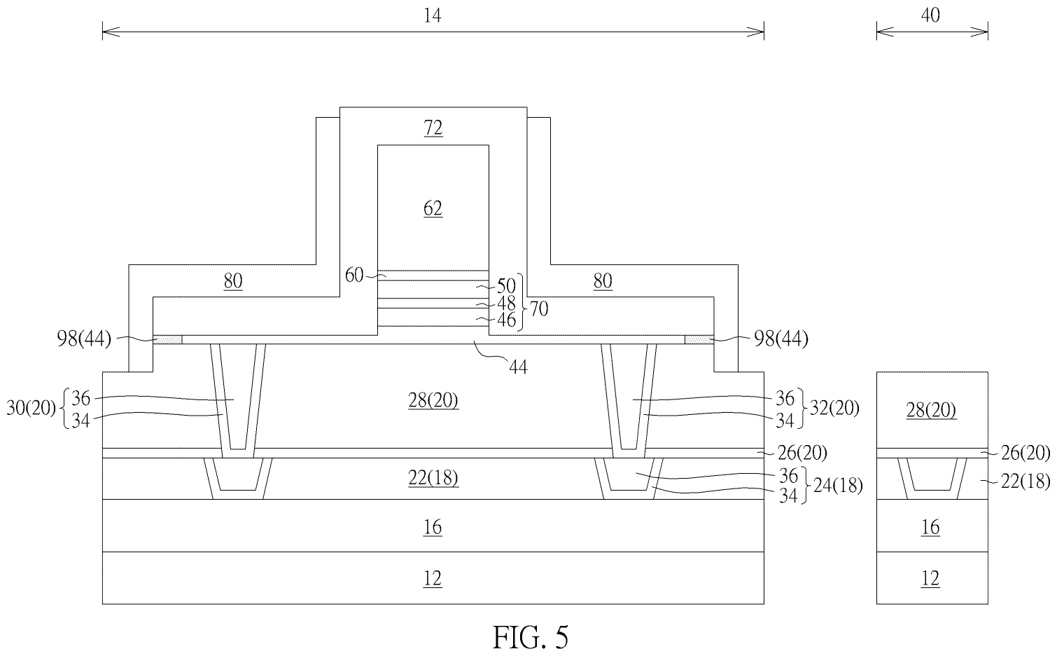

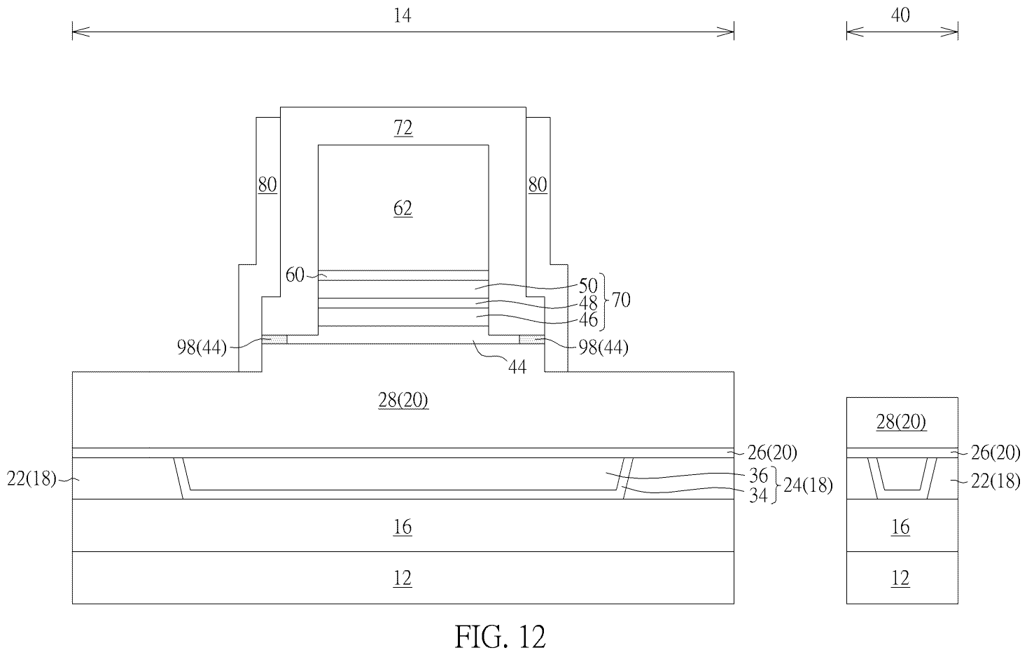

Next, as shown in FIGS. 5 and 12, an etching process is conducted without forming other patterned mask to remove part of the second cap layer 80 on the MRAM region 14 and all of the second cap layer 80 on the logic region 40 for exposing the top surface of the IMD layer 28.

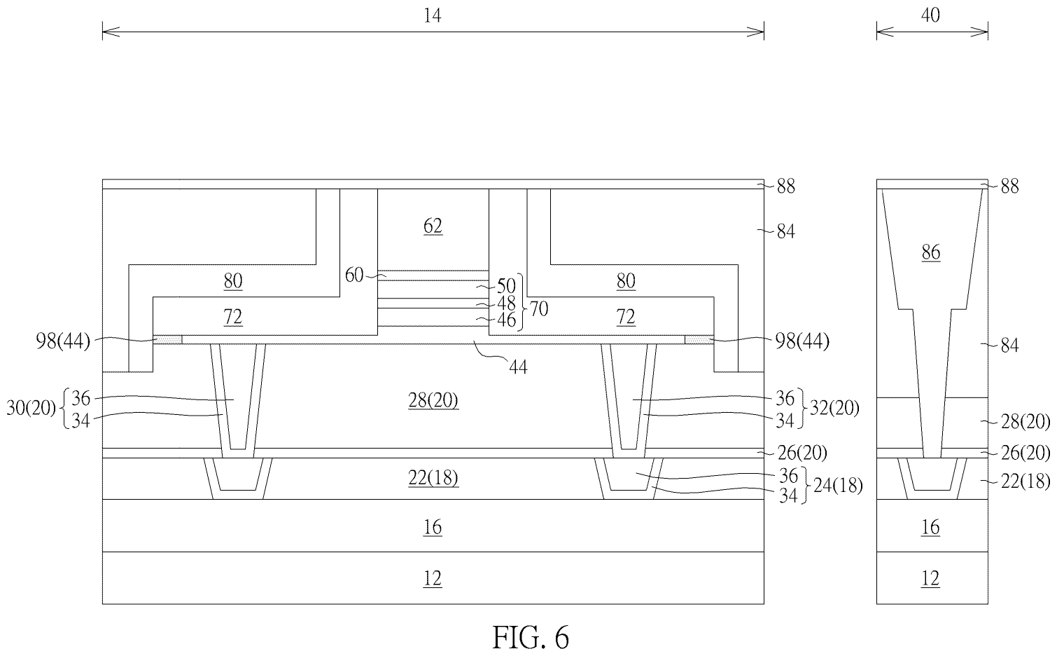

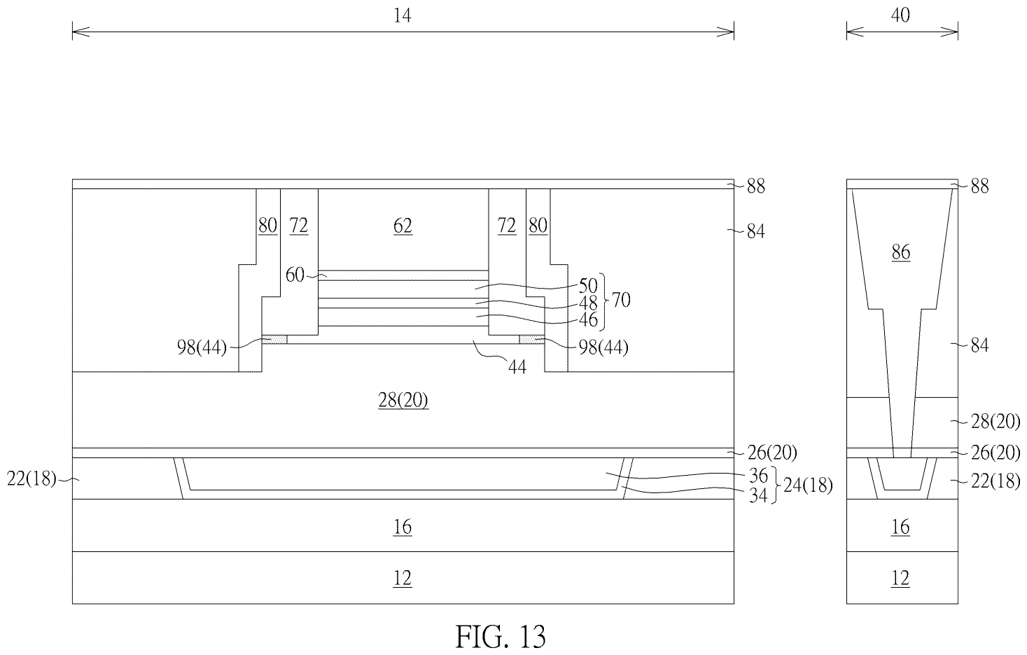

Next, as shown in FIGS. 6 and 13, an IMD layer 84 is formed on the MRAM region 14 and logic region 40, a planarizing process such as chemical mechanical polishing (CMP) is conducted to remove part of the IMD layer 84, part of the second cap layer 80, and part of the first cap layer 72 so that the top surfaces of the remaining IMD layer 84 and TE 62 are coplanar, and then a pattern transfer process is conducted by using a patterned mask (not shown) to remove part of the IMD layer 84, part of the IMD layer 28, and part of the stop layer 26 on the logic region 40 to form a contact hole (not shown) exposing the metal interconnection 24 underneath and conductive materials are deposited into the contact holes afterwards. For instance, a barrier layer selected from the group consisting of titanium (Ti), titanium nitride (TiN), tantalum (Ta), and tantalum nitride (TaN) and metal layer selected from the group consisting of tungsten (W), copper (Cu), aluminum (Al), titanium aluminide (TiAl), and cobalt tungsten phosphide (CoWP) could be deposited into the contact holes, and a planarizing process such as CMP could be conducted to remove part of the conductive materials including the aforementioned barrier layer and metal layer to form a metal interconnection 86 in the contact hole electrically connecting the metal interconnection 24. Next, a stop layer 88 is formed on the TE 62 and the metal interconnections 86. In this embodiment, the IMD layer 84 preferably includes silicon oxide and the stop layer 88 could include SiO₂, SiN, or SiCN.

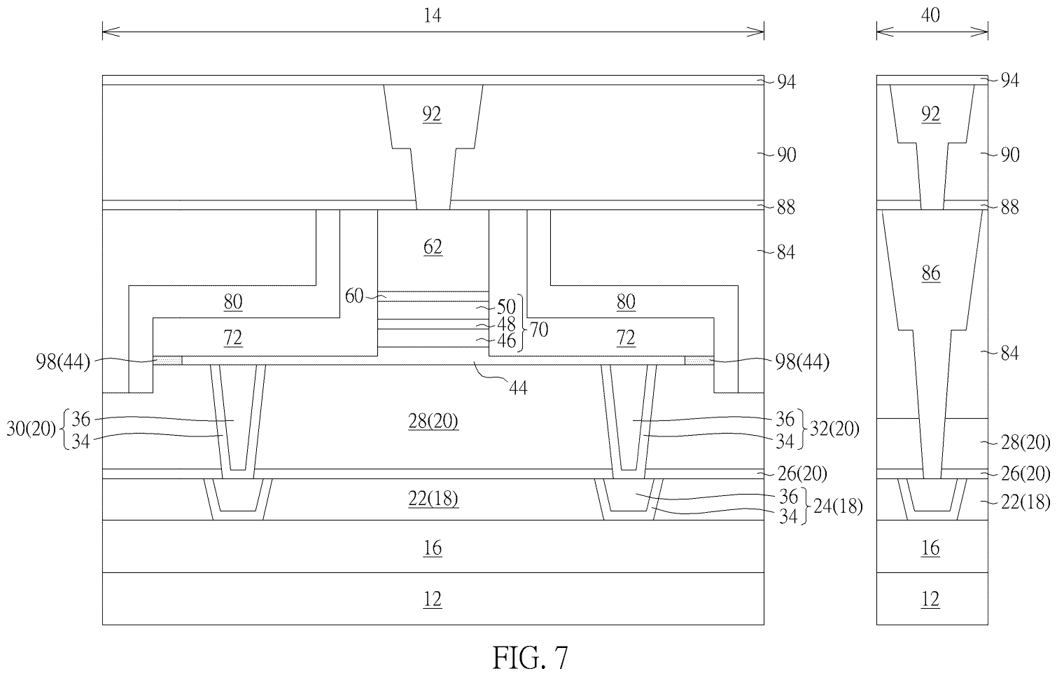

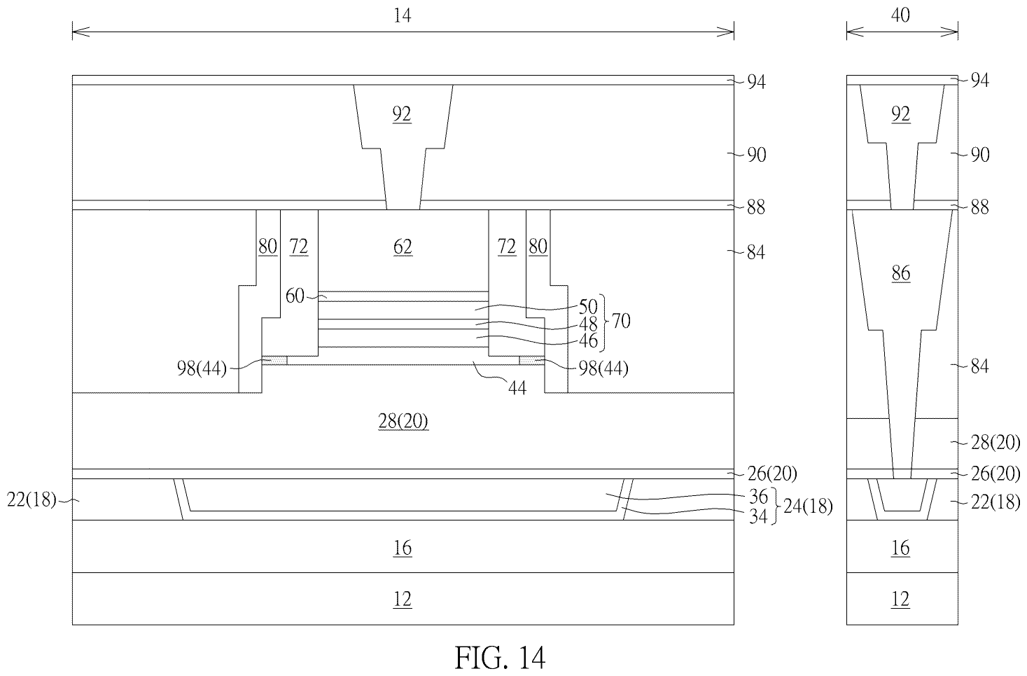

Next, as shown in FIGS. 7 and 14, an IMD layer 90 is formed on the stop layer 88 of the MRAM region 14 and logic region 40, and a pattern transfer process is conducted by using a patterned mask (not shown) to remove part of the IMD layer 90 and part of the stop layer 88 for forming contact holes (not shown) exposing the TE 62 and the metal interconnection 86 and conductive materials are deposited into the contact hole afterwards. For instance, a barrier layer selected from the group consisting of titanium (Ti), titanium nitride (TiN), tantalum (Ta), and tantalum nitride (TaN) and metal layer selected from the group consisting of tungsten (W), copper (Cu), aluminum (Al), titanium aluminide (TiAl), and cobalt tungsten phosphide (CoWP) could be deposited into the contact holes, and a planarizing process such as CMP could be conducted to remove part of the conductive materials including the aforementioned barrier layer and metal layer to form metal interconnections 92 in the contact holes electrically connecting the TE 62 and the metal interconnection 86. Next, a stop layer 94 is formed on the metal interconnection 92. In this embodiment, the IMD layer 90 preferably includes an ultra low-k (ULK) dielectric layer including but not limited to for example porous material or silicon oxycarbide (SiOC) or carbon doped silicon oxide (SiOCH).

Referring again to FIGS. 7 and 14, FIGS. 7 and 14 each illustrate a structural view of a MRAM device according to an embodiment of the present invention. As shown in FIGS. 7 and 14, the MRAM device includes a SOT layer 44 disposed on the substrate 12, a MTJ 70 disposed on the SOT layer 44, a doped region 98 disposed in the SOT layer 44 on one side such as left side of the MTJ 70, another doped region 98 disposed in the SOT layer 44 on another side such as right side of the MTJ 70. Preferably, edges of the doped regions 98 are aligned with sidewalls of the first cap layer 72 atop, the second cap layer 80 contacts sidewalls of the first cap layer 72 and the doped regions 98, and the doped regions 98 constitute a ring surrounding the MTJ 70 under a top view perspective. According to an embodiment of the present invention, the doped regions 98 preferably include metal nitride such as tungsten nitride (WNₓ).

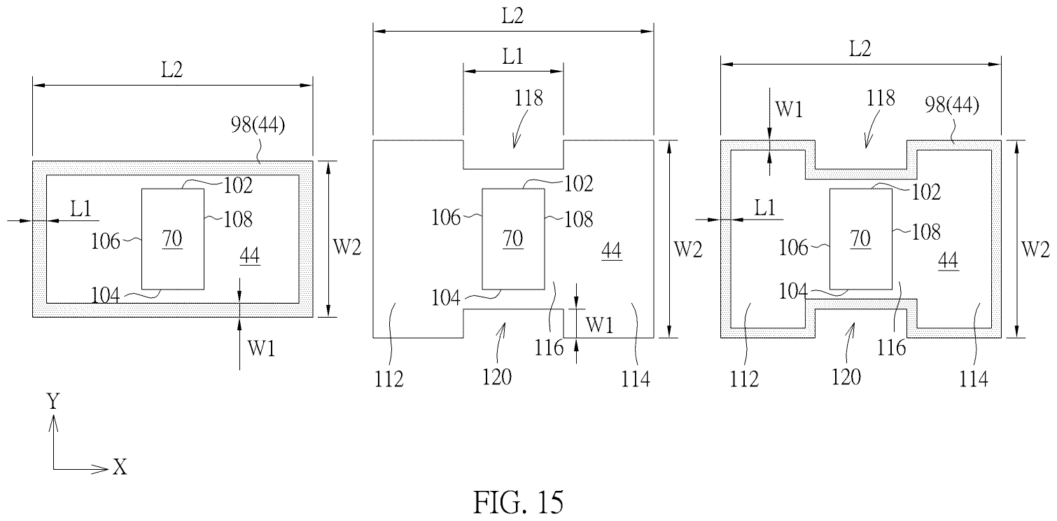

Referring to FIG. 15, FIG. 15 illustrates top views of a MRAM device according to different embodiments of the present invention. As shown in FIG. 15, the MRAM device fabricated according to the aforementioned process preferably includes a SOT layer 44 disposed on the substrate 12, a MTJ 70 disposed on the SOT layer 44, and a doped region 98 in the SOT layer 44 and surrounding the MTJ 70. Preferably, the MTJ 70 has a short side 102 and another short side 104 extending along the X-direction and a long side 106 and another long side 108 extending along the Y-direction, in which the edges of the short sides 102, 104 could be aligned with or not aligned with the edge of the SOT layer 44.

First, as shown on the left portion of FIG. 15, the SOT layer 44 could include a rectangular shape extending along the X-direction on the substrate 12, the MTJ 70 could extend along the Y-direction on the substrate 12, and the doped region 98 could be disposed along the edge of the SOT layer 44 to surround the entire MTJ 70. Since the SOT layer 44 includes a rectangular shape under top view perspective, each of the inner sidewall and outer sidewall of the doped region 98 also includes a rectangular shape.

In this embodiment, the inner sidewall and outer sidewall of the doped region 98 include a length L1 extending along the X-direction therebetween, the outer sidewall of the doped region 98 includes a length L2 extending along the X-direction, the inner sidewall and outer sidewall of the doped region 98 include a width W1 extending along the Y-direction therebetween, and the outer sidewall of the doped region 98 includes a width W2 extending along the Y-direction. Preferably, a ratio of the length L1 to the length L2 or L1/L2 is between 0.1-0.3 and the ratio of the width W1 to the width W2 or W1/W2 is between 0.05-0.15.

Next, as shown on the central portion of FIG. 15, the SOT layer 44 could also include a H-shape on the substrate 12 while the MTJ 70 is also extending along the Y-direction on the SOT layer 44. Specifically, the H-shape of the SOT layer 44 includes a first portion 112 and a second portion 114 extending along the Y-direction and a third portion 116 extending along the X-direction to connect the first portion 112 and the second portion 114, in which the MTJ 70 is extending along the Y-direction on the central region of the third portion 116.

In this embodiment, the SOT layer 44 includes a recess 118 facing toward the short side 102 of the MTJ 70 and another recess 120 facing toward another short side 104 of the MTJ 70. Preferably, each of the recesses 118, 120 includes a length L1 extending along the X-direction, the entire H-shape of the SOT layer 44 includes another length L2 extending from the edge of the first portion 112 to the edge of the second portion 114 along the X-direction, each of the recesses 118, 120 includes a width W1 extending along the Y-direction, and the first portion 112 or second portion 114 of the SOT layer 44 includes another width W2 extending along the Y-direction. Preferably, the ratio of the length L1 to the length L2 or L1/L2 is between 0.2-0.6 and the ratio of the width W1 to the width W2 or W1/W2 is between 0.2-0.5.

Next, as shown on the right portion of FIG. 15, according to yet another aspect of the present invention it would also be desirable to combine the doped region 98 and the H-shape of the SOT layer 44 from aforementioned embodiments so that a doped region 98 could be formed along the edge of the H-shaped SOT layer 44 to surround the MTJ 70 as the doped region 98 could include the aforementioned recess 118 facing toward the short side 102 of the MTJ 70 and another recess 120 facing toward another short side 104 of the MTJ 70. Preferably, the doped region 98 includes a length L1 extending along the X-direction, the entire H-shape of the SOT layer 44 includes another length L2 extending from the edge of the first portion 112 to the edge of the second portion 114 along the X-direction, the doped region 98 includes a width W1 extending along the Y-direction, and the first portion 112 or second portion 114 of the SOT layer 44 includes another width W2 extending along the Y-direction. In this embodiment, the ration of the length L1 to the length L2 or L1/L2 is between 0.025-0.1 and the ratio of the width W1 to the width W2 or W1/W2 is between 0.025-0.075.

Overall, the present invention discloses a method for fabrication MRAM device and relating structure thereof, which first forms a MTJ on the SOT layer, covers a patterned first cap layer 72 on the MTJ and the SOT layer, and then conducts a tilt angle ion implantation process by using a patterned mask as mask to inject nitrogen based dopants into the SOT layer adjacent to two sides of the first cap layer and even part of the SOT layer directly under the first cap layer for forming doped regions 98. Preferably, the doped regions 98 under a top view perspective are disposed along the edge of the SOT layer to surround the MTJ and according to some embodiments could have rectangular shape or H-shape depending on different shapes of the SOT layer. By using tilt angle ion implantation process to implant nitrogen gas into the SOT layer adjacent to two sides the MTJ for forming doped regions, overall efficiency of the SOT layer could be improve effectively.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a magnetoresistive random access memory (MRAM) device, comprising:
forming a spin orbit torque (SOT) layer on a substrate;
forming a magnetic tunneling junction (MTJ) on the SOT layer;
forming a first cap layer adjacent to the MTJ;
performing an ion implantation process to form a first doped region in the SOT layer.

2. The method of claim 1, further comprising:
forming a first inter-metal dielectric (IMD) layer on the substrate;
forming the SOT layer on the first IMD layer;
forming the first cap layer on the MTJ and the SOT layer;
performing the ion implantation process to form the first doped region in the SOT layer adjacent to one side of the MTJ;
forming a second cap layer on the first cap layer; and
forming an second IMD layer on the second cap layer.

3. The method of claim 2, wherein a bottom surface of the second cap layer is lower than a bottom surface of the first cap layer.

4. The method of claim 2, further comprising performing the ion implantation process to form a second doped region in the SOT layer adjacent to another side of the MTJ.

5. The method of claim 4, wherein sidewalls of the second doped region and the first cap layer are aligned.

6. The method of claim 4, wherein first doped region and the second doped region constitute a ring around the MTJ in a top view.

7. The method of claim 1, wherein sidewalls of the first doped region and the first cap layer are aligned.

8. The method of claim 1, wherein the ion implantation process comprises a tilt angle ion implantation process.

9. A magnetoresistive random access memory (MRAM) device, comprising:
a spin orbit torque (SOT) layer on a substrate;
a magnetic tunneling junction (MTJ) on the SOT layer;
a first doped region in the SOT layer adjacent to one side of the MTJ; and
a second doped region in the SOT layer adjacent to another side of the MTJ.

10. The MRAM device of claim 9, further comprising:
a first inter-metal dielectric (IMD) layer on the substrate;
the SOT layer on the first IMD layer;
a first cap layer adjacent to the MTJ and the SOT layer;
a second cap layer on the first cap layer; and
a second IMD layer on the second cap layer.

11. The MRAM device of claim 10, wherein sidewalls of the first doped region and the first cap layer are aligned.

12. The MRAM device of claim 10, wherein sidewalls of the second doped region and the first cap layer are aligned.

13. The MRAM device of claim 10, wherein a bottom surface of the second cap layer is lower than a bottom surface of the first cap layer.

14. The MRAM device of claim 9, wherein first doped region and the second doped region constitute a ring around the MTJ in a top view.

15. A magnetoresistive random access memory (MRAM) device, comprising:
a spin orbit torque (SOT) layer on a substrate;
a magnetic tunneling junction (MTJ) on the SOT layer; and
a doped region in the SOT layer to surround the MTJ, wherein doped region comprises a first recess in a top view.

16. The MRAM device of claim 15, wherein the MTJ comprises:
a first short side;
a second short side;
a first long side; and
a second long side.

17. The MRAM device of claim 16, wherein the first recess faces the first short side.

18. The MRAM device of claim 15, wherein the doped region comprises a second recess in a top view.

19. The MRAM device of claim 18, wherein the second recess faces the second short side.
